(19) United States
(12) Patent Application Publication
(10) Pub. No.: US 2007/0249188 A1
(43) Pub. Date: Oct. 25, 2007

(54) Device for the Shakeproof Accomodation of Electrical Special Components and/or Electrical Circuits

(75) Inventors: Wolfgang Mueller, Schwieberdingen (DE); Thomas Uhland, Pfaffenhofen-Weiler (DE); Dirk Schmidt, Kirchheim (DE); Ibrahim Degirmenci, Vaihingen (DE); Frank Distler, Munster (DE)

Correspondence Address: KENYON & KENYON LLP, ONE BROADWAY, NEW YORK, NY, 10004, US

(73) Assignee: ROBERT BOSCH GMBH, Stuttgart (DE)

(21) Appl. No.: 10/588,142

(22) PCT Filed: Nov. 30, 2004
(86) PCT No.: PCT/EP04/53177

§ 371 Date: Jun. 8, 2007

(30) Foreign Application Priority Data
Jan. 30, 2004 (DE) 10 2004 004 741.3

(51) Int. Cl. H05K 1/18; H01R 13/46

(52) U.S. Cl. 439/76.1; 439/892

(57) ABSTRACT

A device for the shakeproof accommodation of electrical special components and/or electrical circuits, particularly in a development as a second component set in a control unit, is made up of a carrier, onto which a circuit substrate, having special components fastened to it, is mounted in an electrically insulated manner over a partial surface, preferably by adhesion

### FIELD OF THE INVENTION

The present invention relates to a device for the shakeproof accommodation of electrical special components and/or electrical circuits, particularly in a development as a second component set in a control unit.

### BACKGROUND INFORMATION

To accommodate electrical special components, such as capacitors, relays and the like, a carrier is known that is made up of a pressed screen that is extrusion-coated with plastic. In this context, the components are welded to bifurcated contacts that are a part of the pressed screen, and using an adhesive bead situated between the component and the carrier, the special components are held to the carrier. The carrier itself is fastened to a floor of the control unit, using screws. For fastening special components to a printed-circuit board, there are furthermore alternative supports which prevent a relative motion of the special component.

In practice, it has turned out that, especially in use in motor vehicles, the printed-circuit boards get into vibration, and, in this context, there is the danger that the special components, which have a certain mass of their own, will come loose.

### SUMMARY OF THE INVENTION

The present invention is therefore based on the object of making available a device for the shakeproof accommodation of electrical special components and/or electrical circuits which will ensure a secure holding of the special components in response to various vibrational stimulations.

Based on the design of the device according to the present invention, great static and great dynamic stability is achieved, since the circuit substrate is connected to the carrier in a vibration-damping manner. The concept according to the present invention makes possible at the same time the use of various components, designs and circuits without great effort to make changes, the possibility existing, in addition, of implementing the size of a control unit by a displacement of the special components, and, if necessary, the circuits into a second electrical plane.

In the device according to the present invention, one may advantageously achieve a great flexibility in making a component change, and the use of other components and designs is made possible by a simple layout change.

Because of the fixed connection of the circuit substrate to the carrier, a very good temperature resistance is attained in addition. The power loss is reduced, since a heat dissipation is possible via the carrier into the floor of the control unit.

The circuit substrate according to the present invention is preferably applied via an electrically insulating medium over at least the partial surface. This insulating medium may be made up of an insulating foil, advantageously having heat conducting properties. The application onto the carrier is able to take place in individual sections or over the whole surface, especially by using an adhesive. The carrier may have passages, in this context, for contact pins to pass through, and accordingly is in such areas not connected to the circuit substrate.

According to one preferred embodiment of the present invention, the application of the circuit substrate onto the carrier takes place after assembling the circuit substrate, particularly using SMD components. It is preferably provided that circuit substrates fastened to the carrier are able to be connected to the control unit via pins or a flex foil or a plug connection.

The pins fastened to the circuit substrate may preferably be developed as a pin strip, SMD pins, punched bent parts or male pin connectors.

When using a pin strip, according to one further preferred embodiment, it is provided that the pin strip is situated on a tab of the circuit substrate which protrudes outwards over the substrate. This advantageously imparts to the pins an additional elastic property which contributes to securing the contact connection and to reducing vibrational excitations on the circuit substrate.

Alternatively, in order to save a manufacturing step, the pin strip may be pressed into the circuit substrate as male pin connector, the male pin connector being soldered to a main board.

Alternatively, a connection may also be made between circuit substrate and control unit via the SMD pins which are soldered onto the circuit part, and which extend downwards via lateral edges of the substrate for connection to a main board. Because of this, too, a good vibration decoupling of the circuit substrate is made possible.

According to another embodiment of the present invention, the circuit substrate has screw openings for the pass-through of fastening screws that are able to be screwed into the floor of the control unit.

The carrier is preferably made up of cast aluminum and thereby it combines the advantages of great rigidity with those of good heat dissipation. When the carrier is made of cast aluminum, the circuit substrate is applied in an electrically insulated manner via an electrically insulating medium, such as a plastic foil. However, if the carrier is alternatively made of a material that is electrically non-conducting, the circuit substrate, having special components fastened on it, may be directly mounted, at least over part of the surface.

### BRIEF DESCRIPTION OF THE DRAWINGS

FIG. 1 shows a slanted perspective top view onto a first exemplary embodiment of a device according to the present invention, in which a connection to a main board is provided via a pin strip.

FIG. 2 shows a slanted perspective top view onto a second exemplary embodiment of a device according to the present invention, in which SMD pins are provided for an electrical connection to the main board.

### DETAILED DESCRIPTION

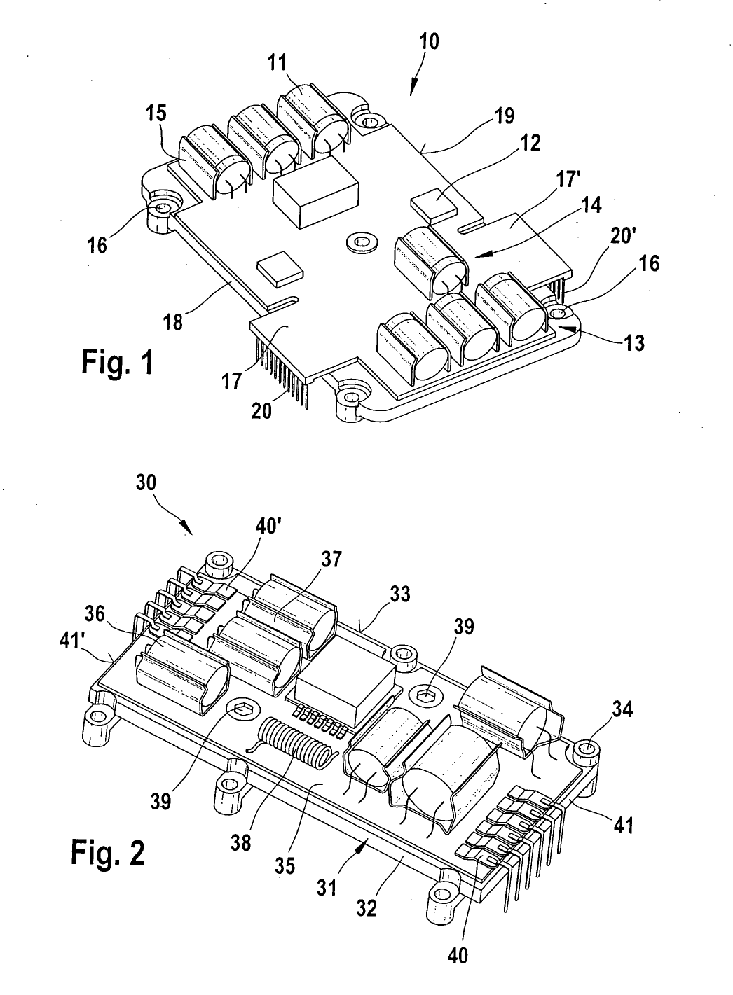

FIG. 1 shows a first exemplary embodiment of a device 10, according to the present invention, for the shakeproof accommodation of special components 11, 12. Device 10 is made up of a plate-shaped carrier 13 made of cast aluminum, onto which at least over part of the surface a circuit substrate 14 in the form of a printed-circuit board is adhered. Circuit substrate 14 additionally has a holder 15 for the vibration resistant fastening of special components 11, such as capacitors. Other special components, such as structural element 12, are fastened to circuit substrate 14 by SMD technology.

In the areas of its four corners, carrier 13 has screw openings 16, which are provided for the pass-through of fastening screws, that are not shown, for fastening carrier 11, for instance, to a control unit that is not shown.

Circuit substrate 14 has tabs 17 on opposite sides, which in each case protrude beyond sides 18 and 19 of the carrier, and on which pin strips 20 and 20′, made of a plastic holder, and into which the pins are fused, are fastened by soldering. The pins are given an additional elastic property by the fastening at tab 17 and 17′.

Alternatively, pin strips 20 and 20′ may be replaced by a male pin connector, that is not shown, by a pressing-in technique, in order to save a manufacturing step. In this context, the male pin connector is pressed into the circuit substrate, and is then able to be connected to a main board by soldering.

FIG. 2 shows an additional exemplary embodiment of a device 30 according to the present invention for the shakeproof accommodation of electrical special components and/or electrical circuits, in particular, in a development as a second component set in a control unit. In device 30 a carrier 31 is provided which is also made up of cast aluminum and is developed as a rectangular plate, at whose sides 32 and 33 in each case three screw openings 34 are premolded.

Onto carrier 31 a circuit substrate 35 in the form of a printed-circuit board is adhered, and onto this, special components 36 are fastened and adhered using a holder 37 and SMD component parts. Additional screws are indicated by 39, which, instead of a holding-down device for the printed-circuit board that is not shown, are inserted upon the curing of an adhesive.

On circuit substrate 35, in the area of opposite end faces 41 and 41′ of carrier 31, SMD pin devices 40, 40′ are soldered to produce an electrical connection to a main board. The individual pins of SMD pin device 40 and 40′ extend downwards at a distance from end faces 41, 41′, and are able to be connected to an additional board, that is not shown, for instance, a main board, by solder pot soldering or the flow solder method.

1.-13. (canceled)

14. A device for a shakeproof accommodation of at least one of an electrical special component and an electrical circuit, comprising:
a carrier onto which a circuit substrate having the special component fastened thereon is mounted in an electrically insulated manner at least over a partial surface.

15. The device as recited in claim 14, further comprising an electrically insulating medium provided between the carrier and the circuit substrate.

16. The device as recited in claim 14, wherein the circuit substrate is fastened to the carrier by one of a heat-dissipating adhesive, a laminated-on adhesive foil, screws, rivets and crimping.

17. The device as recited in claim 14, wherein the circuit substrate includes one of a printed-circuit board, a flex foil, a ceramic, and a wire harness.

18. The device as recited in claim 14, wherein the carrier has passages for contact pins that pass through.

19. The device as recited in claim 14, wherein the circuit substrate fastened to the carrier is able to be connected to a control unit via pins.

20. The device as recited in claim 19, wherein the pins include one of a pin strip, SMD pins, punched bent parts, and male pin connectors.

21. The device as recited in claim 20, wherein the pin strip is situated on a tab, of the circuit substrate, which protrudes outwards over the carrier.

22. The device as recited in claim 20, wherein each pin strip is pressed into the circuit substrate.

23. The device as recited in claim 20, wherein the SMD pins are soldered onto the circuit substrate and extend downwards via lateral edges of the carrier to connect to a main board.

24. The device as recited in claim 14, wherein the circuit substrate fastened to the carrier is able to be connected to the control unit via a flex foil and a plug connection.

25. The device as recited in claim 14, wherein the carrier has screw openings for a passage of especially fastening screws that are able to be screwed into a floor of a control unit.

26. The device as recited in claim 14, wherein the carrier is made of cast aluminum.

27. The device as recited in claim 14, wherein the shakeproof accommodation is in a development as a second component set for a control unit.
